(19) United States
(12) Patent Application Publication
(10) Pub. No.: US 2020/0106003 A1
(43) Pub. Date: Apr. 2, 2020

(54) OPTIMIZED PERPENDICULAR MAGNETIC FREE LAYER STACK WITH A CRYSTALLINE GRAIN GROWTH CONTROLLING LAYER

(71) Applicant: International Business Machines Corporation, Armonk, NY (US)

(72) Inventors: Matthias Georg Gottwald, New Rochelle, NY (US); Janusz J. Nowak, Highland Mills, NY (US)

(21) Appl. No.: 16/144,519

(22) Filed: Sep. 27, 2018

(51) Int. Cl. H01L 43/08; H01L 43/10; H01L 43/12; H01L 27/22

(52) U.S. Cl. CPC H01L 43/08; H01L 43/10; G11C 11/161; H01L 27/222; H01L 43/12

(57) ABSTRACT

A crystal grain growth controlling dusting layer is added to a magnetic free layer stack of a magnetic tunnel junction structure. The crystal grain growth controlling dusting layer, which is inserted between first and second magnetic layers of the magnetic free layer stack, is composed of a non-magnetic material that is capable of improving the grain growth homogeneity of the various components of the magnetic tunnel junction structure by slowing down grain growth dynamics and by controlling oxygen diffusion. The homogenization of the grain growth and oxygen distribution allows low write error rates and low write error rate slopes spin-transfer torque magnetic random access memory devices.

### BACKGROUND

The present application relates to magnetoresistive random access memory (MRAM). More particularly, the present application relates to a perpendicular magnetic tunnel junction (MTJ) structure including a magnetic free layer stack containing a crystalline grain growth controlling layer that can improve the performance of spin-transfer torque MRAM.

Spin-transfer torque MRAM uses a 2-terminal device as is shown in FIG. 1 that includes a magnetic tunnel junction (MTJ) structure that contains a magnetic reference (or pinned) layer 10, a tunnel barrier layer 12, a magnetic free layer 13 and a capping layer 20. The magnetization of the pinned layer 10 is fixed in direction (say pointing up) and a current passed down through the junction makes the magnetic free layer 13 parallel to the pinned layer 10, while a current passed up through the junction makes the magnetic free layer 13 anti-parallel to the pinned layer 10. A smaller current (of either polarity) is used to read the resistance of the device, which depends on the relative orientations of the magnetizations of the magnetic free layer 13 and the pinned layer 10. The resistance is typically higher when the magnetizations are antiparallel, and lower when they are parallel (though this can be reversed, depending on the material).

Prior art spin-transfer torque MRAMs may also include a MTJ structure that contains a magnetic free layer stack 14 that contains at least two magnetic layers (16, 18) as shown in FIG. 2. The material of the first magnetic layer 16 of the magnetic free layer stack 14 is chosen for optimizing the tunnel barrier layer 12/first magnetic layer 16 interface. Examples for such optimization might be high TMR (tunneling magneto resistance: ratio of ([high resistance state-low resistance state]/low resistance state)), high interface anisotropy or good interface wetting. The material of the second magnetic layer 18 of the magnetic free layer stack 14 is chosen to optimize the interface between the second magnetic layer 18 and the cap layer 20. Examples for such optimization might be high interface anisotropy and low moment. Both parts of the magnetic free layer stack 14, i.e., the first magnetic layer 16 and the second magnetic layer 18, can contain multiple sub-layers for further optimization.

For prior art MTJ structures such as shown in FIG. 2, it is a challenge to reach low write error rates and high write error rate uniformity after high temperature annealing cycles (for example, 400° C. or greater) are performed. The reason is suspected to be related to uncontrolled crystalline grain growth and oxygen redistribution within the magnetic free layer(s), the capping layer and the tunnel barrier layer.

There is thus a need for providing a MTJ structure including a magnetic free layer stack that can improve the performance of spin-transfer torque MRAM even after a high temperature annealing process has been performed.

### SUMMARY

A crystal grain growth controlling dusting layer is added to a magnetic free layer stack of a magnetic tunnel junction structure. The crystal grain growth controlling dusting layer, which is inserted between first and second magnetic layers of the magnetic free layer stack, is composed of a non-magnetic material that is capable of improving the grain growth homogeneity of the various components of the magnetic tunnel junction structure by slowing down grain growth dynamics and by controlling oxygen diffusion. The homogenization of the grain growth and oxygen distribution allows low write error rates and low write error rate slopes spin-transfer torque magnetic random access memory devices.

In one aspect of the present application, a magnetic tunnel junction (MTJ) structure is provided. In one embodiment, the MTJ structure includes a magnetic free layer stack of a first magnetic layer and a second magnetic layer. In accordance with the present application, a crystal grain growth controlling dusting layer is positioned between the first and second magnetic layers of the magnetic free layer stack.

In another aspect of the present application, a spin-transfer torque magnetic random access memory (MRAM) that has improved performance is provided. In one embodiment, the spin-transfer torque MRAM includes a tunnel barrier layer located on a surface of a magnetic reference layer. A magnetic free layer stack is located on the tunnel barrier layer. The magnetic free layer stack includes a first magnetic layer and a second magnetic layer, wherein a crystal grain growth controlling dusting layer is positioned between the first and second magnetic layers of the magnetic free layer stack, and wherein the first magnetic layer of the magnetic free layer stack is located on a surface of the tunnel barrier layer.

In yet another aspect of the present application, a method of improving the performance of a spin-transfer torque magnetic random access memory is provided. In one embodiment, the method includes forming a tunnel barrier layer on a surface of a magnetic reference layer. Next, a magnetic tunnel junction structure is formed on the tunnel barrier layer. In accordance with the present application, the magnetic tunnel junction structure includes a magnetic free layer stack of a first magnetic layer and a second magnetic layer, wherein a crystal grain growth controlling dusting layer is positioned between the first and second magnetic layers of the magnetic free layer stack, and wherein the first magnetic layer of the magnetic free layer stack forms an interface with a surface of the tunnel barrier layer.

### BRIEF DESCRIPTION OF THE DRAWINGS

FIG. 1 is a cross sectional view of a prior art MTJ structure including a magnetic reference (or pinned) layer, a tunnel barrier, and a magnetic free layer.

FIG. 2 is a cross sectional view of a prior art MTJ structure including a magnetic free layer stack which includes two magnetic layers separated by a non-magnetic layer.

FIG. 3 is a cross sectional view of an exemplary MTJ structure in accordance with one embodiment of the present application.

FIG. 4 is a graph illustrating the write error rate of a prior art MTJ structure; the y-axis is in normal quantile scale, and vfrc stands for applied pulse voltage.

FIG. 5 is a graph illustrating the write error rate of another MTJ structure of the present application; the y-axis is in normal quantile scale, and vrfc stands for the applied pulse voltage.

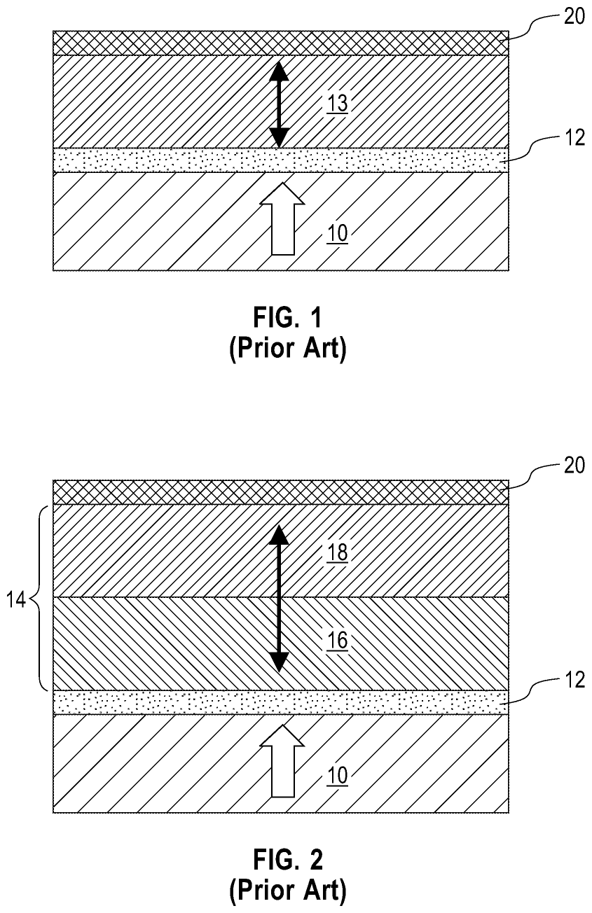

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Applicant has unexpectedly determined that the insertion of a crystal grain growth controlling dusting layer, as defined in greater detail herein below, into a magnetic free layer stack of a magnetic tunnel junction structure can improve the performance, in terms of low write error rates and low write error rate slopes, of a spin-transfer torque magnetic random access memory. The crystal grain growth controlling dusting layer, which is inserted between a first magnetic layer and second magnetic layer of the magnetic free layer stack, is composed of a non-magnetic material that is capable of improving the grain growth homogeneity of the various components of the magnetic tunnel junction structure by slowing down grain growth dynamics and by controlling oxygen diffusion during a subsequently performed high temperature annealing (i.e., 400° C. or greater). The homogenization of the grain growth and oxygen distribution allows for improved spin-transfer torque device performance.

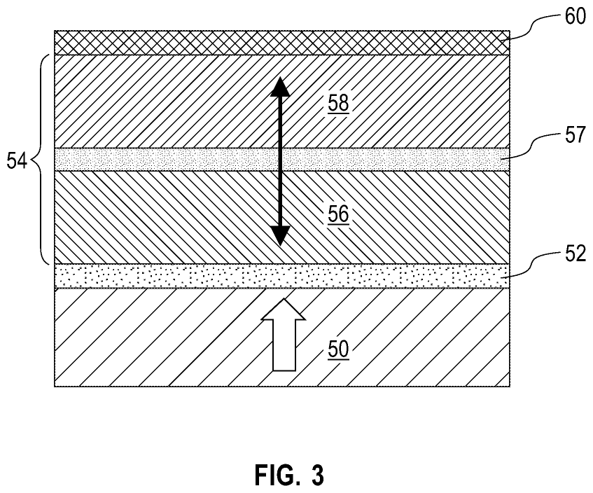

Referring first to FIG. 3, there is illustrated an exemplary MTJ structure in accordance with one embodiment of the present application. The MTJ structure of FIG. 3 includes a magnetic reference layer 50, a tunnel barrier layer 52 located on a surface of the magnetic reference layer 50, a magnetic free layer stack 54 located on a surface of the tunnel barrier layer 52, and a capping layer 60 located on a surface of the magnetic free layer stack 54. The magnetic free layer stack 54 includes a first magnetic layer 56, a crystalline grain growth controlling dusting layer 57 and a second magnetic layer 58. The first magnetic layer 56 of the magnetic free layer stack 54 forms a first interface with tunnel barrier layer 52 and a second interface with the crystalline grain growth controlling dusting layer 57. The second magnetic layer 58 of the magnetic free layer stack 54 forms a first interface with the crystalline grain growth controlling dusting layer 57 and a second interface with the capping layer 60. It is noted that the first and second magnetic layers (56 and 58) of the magnetic free layer stack 54 may be composed of various sub-layers. The magnetic reference layer 50 can be formed on a surface of a conductive landing pad (not shown) and the entire MTJ structure of FIG. 3 may be embedded in a back-end-of-the-line (BEOL) interconnect dielectric material.

The magnetic reference layer 50 that can be employed in the present application has a fixed magnetization. The magnetic reference layer 50 may be composed of a metal or metal alloy that includes one or more metals exhibiting high spin polarization. In alternative embodiments, exemplary metals for the formation of magnetic reference layer 50 include iron, nickel, cobalt, chromium, boron, and manganese. Exemplary metal alloys may include the metals exemplified by the above. In another embodiment, the magnetic reference layer 50 may be a multilayer arrangement having (1) a high spin polarization region formed from of a metal and/or metal alloy using the metals mentioned above, and (2) a region constructed of a material or materials that exhibit strong perpendicular magnetic anisotropy (strong PMA). Exemplary materials with strong PMA that may be used include a metal such as cobalt, nickel, platinum, palladium, iridium, or ruthenium, and may be arranged as alternating layers. The strong PMA region may also include alloys that exhibit strong PMA, with exemplary alloys including cobalt-iron-terbium, cobalt-iron-gadolinium, cobalt-chromium-platinum, cobalt-platinum, cobalt-palladium, iron-platinum, and/or iron-palladium. The alloys may be arranged as alternating layers. In one embodiment, combinations of these materials and regions may also be employed. The thickness of magnetic reference layer 50 will depend on the material selected. In one example, magnetic reference layer 20 may have a thickness from 0.3 nm to 3 nm. The magnetic reference layer 50 can be formed by utilizing a deposition process such as, for example, chemical vapor deposition (CVD), plasma enhanced chemical vapor deposition (PECVD), physical vapor deposition (PVD), or sputtering.

Tunnel barrier layer 52, which is formed on a physically exposed surface of the magnetic reference layer 50, is composed of an insulator material and is formed at such a thickness as to provide an appropriate tunneling resistance. Exemplary materials for the tunnel barrier layer 52 include magnesium oxide, aluminum oxide, and titanium oxide, or materials of higher electrical tunnel conductance, such as semiconductors or low-bandgap insulators. The thickness of the tunnel barrier layer 52 will depend on the material selected. In one example, the tunnel barrier layer 52 may have a thickness from 0.5 nm to 1.5 nm. The tunnel barrier layer 52 can be formed by utilizing a deposition process such as, for example, CVD, PECVD, PVD, or sputtering.

The first magnetic layer 56 of the magnetic free layer stack 54 of the present application, which is formed on a physically exposed surface of the tunnel barrier layer 52, is composed of a magnetic material (i.e., a first magnetic material) with a magnetization that can be changed in orientation relative to the magnetization orientation of the magnetic reference layer 50. Exemplary materials for the first magnetic layer 56 include alloys and/or multilayers of cobalt, iron, alloys of cobalt-iron, nickel, alloys of nickel-iron, and alloys of cobalt-iron-boron. The first magnetic layer 56 may have a thickness from 0.3 nm to 3 nm. The first magnetic layer 56 of the magnetic free layer stack 54 can be formed by utilizing a deposition process such as, for example, CVD, PECVD, PVD, or sputtering.

The crystalline grain growth controlling dusting layer 57, which is formed on a physically exposed surface of the first magnetic layer 56 of the magnetic free layer stack 54, is composed of a non-magnetic material that is capable of improving the grain growth homogeneity of the various components of the magnetic tunnel junction structure by slowing down grain growth dynamics and by controlling oxygen diffusion. In one embodiment of the present application, the crystalline grain growth controlling dusting layer 57 is composed of zirconium (Zr), niobium (Nb) or an alloy of Zr and Nb.

In some embodiments, the crystal grain growth controlling dusting layer 57 is a discrete layer consisting of a non-magnetic material selected from one of zirconium (Zr) and niobium (Nb). In other embodiments, the crystal grain growth controlling dusting layer 57 is alloyed with a non-magnetic material that provides the first magnetic layer 56 of the magnetic free layer stack 54, the second magnetic layer 58 of the magnetic free layer stack 54, or both the first and second magnetic layers (56 and 58) of the magnetic free layer stack 54. In one example, the crystal grain growth controlling dusting layer 57 is composed of Zr or Nb that is alloyed with a cobalt-iron-boron alloy. The crystal grain growth controlling dusting layer 57 may have a thickness from 0.5 Å to 3 Å. The crystal grain growth controlling dusting layer 57 can be formed by utilizing a deposition process such as, for example, CVD, PECVD, PVD, or sputtering.

The second magnetic layer 58 of the magnetic free layer stack 54 is formed on a physically exposed surface of the crystalline grain growth controlling dusting layer 57. The second magnetic layer 58 of the magnetic free layer stack 54 may be composed of a second magnetic material with a magnetization that can be changed in orientation relative to the magnetization orientation of the magnetic reference layer 50. The second magnetic material that provides the second magnetic layer 58 of the magnetic free layer stack 54 can include one of the magnetic materials mentioned above for the first magnetic layer 56 of the magnetic free layer stack 54. In some embodiments, the second magnetic layer 58 of the magnetic free layer stack 54 is composed of a same magnetic material as the first magnetic layer 56 of the magnetic free layer stack 54. In other embodiments, the second magnetic layer 58 of the magnetic free layer stack 54 is composed of a magnetic material that is compositionally different from the magnetic material that provides the first magnetic layer 56 of the magnetic free layer stack 54. The second magnetic layer 58 of the magnetic free layer stack 54 may have a thickness from 0.3 nm to 3 nm. The second magnetic layer 58 of the magnetic free layer stack 54 can be formed by utilizing a deposition process such as, for example, CVD, PECVD, PVD, or sputtering.

In one embodiment of the present application, the magnetic free layer stack 54 is formed by first sputtering the first magnetic layer 56 including the use of a first sputtering target(s), second sputtering the crystal grain growth controlling dusting layer 57 utilizing the first sputtering target(s) plus a second sputtering target of Zn or Nb, and third sputtering the second magnetic layer 58 utilizing a third sputtering target(s). In another embodiment of the present application, the magnetic free layer stack 54 is formed by first sputtering the first magnetic layer 56 including the use of a first sputtering target(s), second sputtering the crystal grain growth controlling dusting layer 57 utilizing a third sputtering target(s) plus a second sputtering target of Zn or Nb, and third sputtering the second magnetic layer 58 utilizing the third sputtering target(s).

Capping layer 60 may include one or more different kinds of oxides. Exemplary oxide materials for the capping layer 60 include metal oxides such oxides of aluminum, oxides of magnesium, oxides of magnesium and titanium, oxides of magnesium and tantalum, oxides of titanium, oxides of tantalum, oxides of tungsten, oxides of iridium, oxides of zirconium, and oxides of ruthenium, among others. In one example, the capping layer 60 includes tantalum oxide and/or ruthenium oxide. In yet other embodiments, the capping layer 60 includes a metal cap such as for example, tantalum and/or ruthenium. The capping layer 60 may have a thickness from 0.5 nm to 2 nm. The capping layer 60 can be formed by utilizing a deposition process such as, for example, CVD, PECVD, PVD, or sputtering.

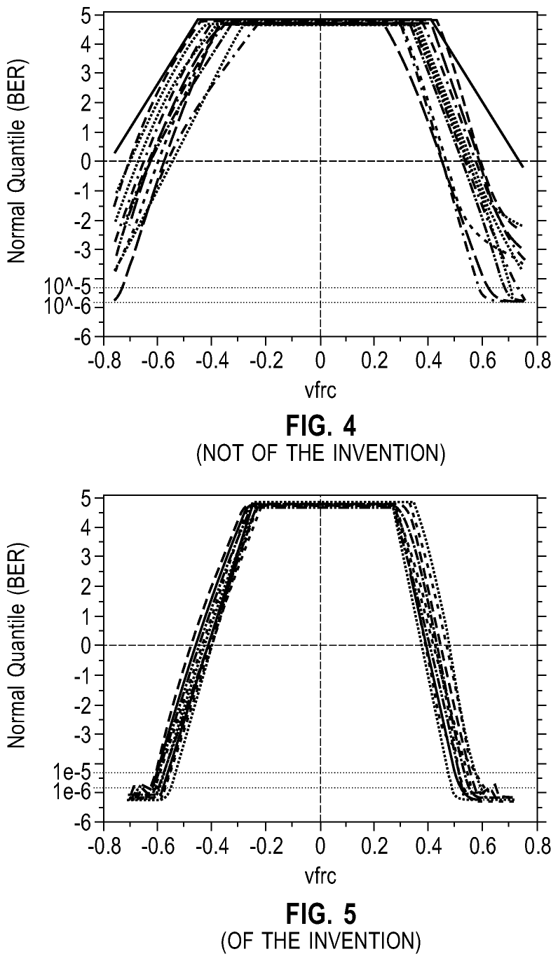

Reference is now made to FIGS. 4 and 5 which are graphs of actual experiments that were performed to illustrate that the insertion of a crystal grain growth controlling dusting layer between first and second magnetic layers of a magnetic free layer stack provides improved device performance, in terms of low write error rates and low write error rate slopes, of a spin-transfer torque magnetic random access memory, after performing a high temperature anneal. FIG. 4 is representative date of a prior art MJT stack that includes first and second magnetic layers of CoFeB without any crystal grain growth controlling dusting layer, while FIG. 5 is representative date of a MTJ stack of the present invention including first and second magnetic layers of CoFeB with 1 Å Zr crystal grain growth controlling dusting layer. The MTJ stacks used in provided the data shown in FIGS. 4 and 5 were identical except for the presence of the Zr crystal grain growth controlling dusting layer. Similar results were observed when Zr was replaced with Nb. Both MTJ structures where annealed at a same annealing temperature.

As observed in FIG. 4, the prior art MTJ structure without crystal grain growth controlling dusting layer had a large variability of 10 ns write voltages. In contrast, and as observed in FIG. 5, the MTJ structure with Zr crystal grain growth controlling dusting layer had a strongly improved variability of 10 ns write voltages for devices of around 35 nm in diameter. Especially the slopes of the write error rate in normal quantile as a function of voltage are much more homogenous for the devices in FIG. 5 with Zr insertion compared to the devices in FIG. 4 without the Zr addition. This allow for strongly improved margins of reaching a low write error rate floor. As those skilled in the art might recognize is that only few devices in FIG. 4 reach write error rates below 1E-5 for voltages below 0.8 V, whereas all devices in FIG. 5 do.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A magnetic tunnel junction structure comprising:
a magnetic free layer stack of a first magnetic layer and a second magnetic layer, wherein a crystal grain growth controlling dusting layer is positioned between the first and second magnetic layer of the magnetic free layer stack.

2. The magnetic tunnel junction structure of claim 1, wherein the crystal grain growth controlling dusting layer is composed of a non-magnetic material selected from one of zirconium (Zr) and niobium (Nb).

3. The magnetic tunnel junction structure of claim 2, wherein the crystal grain growth controlling dusting layer is a discrete layer consisting of the non-magnetic material selected from one of zirconium (Zr) and niobium (Nb).

4. The magnetic tunnel junction structure of claim 2, wherein the non-magnetic material of the crystal grain growth controlling dusting layer is alloyed with a non-magnetic material that provides the first magnetic layer of the magnetic free layer stack, the second magnetic layer of the magnetic free layer stack, or both the first and second magnetic layers of the magnetic free layer stack.

5. The magnetic tunnel junction structure of claim 1, wherein the crystal grain growth controlling dusting layer has a thickness from 0.5 Å to 3 Å.

6. The magnetic tunnel junction structure of claim 1, further comprising a tunnel barrier layer located on a surface of the first magnetic layer of the magnetic free layer stack that is opposite a surface of the first magnetic layer of the magnetic free layer stack that forms an interface with the crystal grain growth controlling dusting layer.

7. The magnetic tunnel junction structure of claim 6, further comprising a magnetic reference layer located on a surface of the tunnel barrier layer that is opposite the surface of the tunnel barrier layer that forms an interface with the first magnetic layer of the magnetic free layer stack.

8. The magnetic tunnel junction structure of claim 7, further comprising a capping layer located on a surface of the second magnetic layer of the magnetic free layer stack that is opposite the surface of the second magnetic layer of the magnetic free layer stack that forms an interface with the crystal grain growth controlling dusting layer.

9. The magnetic tunnel function structure of claim 1, wherein the crystal grain growth controlling dusting layer reduces grain growth and oxygen diffusion in the magnetic free layer stack.

10. A spin-transfer torque magnetic random access memory comprising:
a magnetic reference layer;
a tunnel barrier layer located on a surface of the magnetic reference layer;
a magnetic free layer stack of a first magnetic layer and a second magnetic layer, wherein a crystal grain growth controlling dusting layer is positioned between the first and second magnetic layers of the magnetic free layer stack, and wherein the first magnetic layer of the magnetic free layer stack is located on a surface of the tunnel barrier layer.

11. The spin-transfer torque magnetic random access memory of claim 8, further comprising a capping layer located on a surface of the second magnetic layer of the magnetic free layer stack that is opposite the surface of the second magnetic layer of the magnetic free layer stack that forms an interface with the crystal grain growth controlling dusting layer.

12. The spin-transfer torque magnetic random access memory of claim 8, wherein the crystal grain growth controlling dusting layer is composed of a non-magnetic material selected from one of zirconium (Zr) and niobium (Nb).

13. The spin-transfer torque magnetic random access memory of claim 12, wherein the crystal grain growth controlling dusting layer is a discrete layer consisting of the non-magnetic material selected from one of zirconium (Zr) and niobium (Nb).

14. The spin-transfer torque magnetic random access memory of claim 10, wherein the non-magnetic material of the crystal grain growth controlling dusting layer is alloyed with a non-magnetic material that provides the first magnetic layer of the magnetic free layer stack, the second magnetic layer of the magnetic free layer stack, or both the first and second magnetic layers of the magnetic free layer stack.

15. The spin-transfer torque magnetic random access memory of claim 8, wherein the crystal grain growth controlling dusting layer has a thickness from 0.5 Å to 3 Å.

16. A method of improving the performance of a spin-transfer torque magnetic random access memory, the method comprising:
forming a tunnel barrier layer on a surface of a magnetic reference layer; and
forming a magnetic tunnel junction structure comprising a magnetic free layer stack of a first magnetic layer and a second magnetic layer, wherein a crystal grain growth controlling dusting layer is positioned between the first and second magnetic layers of the magnetic free layer stack, and wherein the first magnetic layer of the magnetic free layer stack forms an interface with a surface of the tunnel barrier layer.

17. The method of claim 16, wherein the crystal grain growth controlling dusting layer is composed of a non-magnetic material selected from one of zirconium (Zr) and niobium (Nb).

18. The method of claim 17, wherein the crystal grain growth controlling dusting layer is a discrete layer consisting of the non-magnetic material selected from one of zirconium (Zr) and niobium (Nb).

19. The method of claim 17, wherein the non-magnetic material of the crystal grain growth controlling dusting layer is alloyed with a non-magnetic material that provides the first magnetic layer of the magnetic free layer stack, the second magnetic layer of the magnetic free layer stack, or both the first and second magnetic layers of the of the magnetic free layer stack.

20. The method of claim 16, wherein the crystal grain growth controlling dusting layer reduces grain growth and oxygen diffusion in the magnetic free layer stack during a subsequently performed annealing process.
